(19) United States
(12) Patent Application Publication
(10) Pub. No.: US 2017/0280591 A1
(43) Pub. Date: Sep. 28, 2017

(54) Heat sink

(71) Applicants: LE HOLDINGS (BEIJING) CO., LTD., Beijing (CN); LE SHI ZHI XIN ELECTRONIC TECHNOLOGY (TIANJIN) LIMITED, Beijing (CN)

(72) Inventors: Erhu MA, Beijing (CN); Guoping YANG, Beijing (CN); Lintao LEI, Beijing (CN); Weiqiang ZHANG, Beijing (CN)

(21) Appl. No.: 15/242,420

(22) Filed: Aug. 19, 2016

Related U.S. Application Data
(63) Continuation of application No. PCT/CN2016/088458, filed on Jul. 4, 2016.

(30) Foreign Application Priority Data
Mar. 23, 2016 (CN) 2016202287960

(51) Int. Cl. H05K 7/20; F28F 21/08; F28F 13/18

(52) U.S. Cl. CPC H05K 7/20418; F28F 13/18; F28F 21/084; H05K 7/20963

(57) ABSTRACT

A heat sink that radiates heat via the metal shell of the electronic device is provided. The upper portion of the heat sink is formed by a solid aluminium block boss, and the lower portion of the heat sink is formed by an aluminium substrate, wherein at least one fin is configured on either side of the solid aluminium block boss.

### CROSS REFERENCE TO RELATED APPLICATIONS

This application is a continuation of International Application No. PCT/CN2016/088458PCT, filed on Jul. 4, 2016, which is based upon and claims priority to Chinese Patent Application No. 201620228796.0, filed on Mar. 23, 2016, the entire contents of which are incorporated herein by reference.

### TECHNICAL FIELD

The present disclosure relates to the technical field of television technology, specifically, involving a heat sink.

### BACKGROUND

Electronic devices follow a trend of metal shell, and the mainstream high-end products increasingly adopt metal materials. Metal shells have the merits of aesthetic appearance, durability and solidity.

In another aspect, the electronic devices usually need for heat radiation. Currently, heat sink is usually adopted for expanding the heat radiating area, so as to facilitate the heat radiation of electronic devices.

It is now urgently required a novel heat sink that can radiate heat via the aluminum sheets in the shells of the electronic devices.

### SUMMARY

Considering the above problem, the present disclosure is to provide a heat sink that can overcome the above problem, or at least partially solve the above problem.

One embodiment of the present disclosure provides a heat sink, an upper portion of which is formed by a solid aluminium block boss, and a lower portion of which is formed by an aluminium substrate, wherein at least one fin is configured on either side of the solid aluminium block boss.

One embodiment of the present disclosure provides a heat sink. When it is mounted between a heat source element and a metal shell of the electronic device, it functions not only for conventional heat radiation, but also to increase a heat radiation path for conducting the heat from the heat sink to an aluminium sheet on the machine shell, and directly radiating the heat outside of the machine by aluminium sheet natural convection and radiation.

The above elaborations are merely a general introduction to the technical solution of the present disclosure. To make the technical means of the present disclosure clearer, so as to implement according to the disclosure of the instant description, and to make the above and other aims, technical features and advantages of the present disclosure more obvious and easier to understand, specific embodiments of the present disclosure are further provided as follows.

### BRIEF DESCRIPTION OF THE DRAWINGS

By reviewing the following detailed elaborations on the preferable embodiment, various other advantages and merits would become clearer to those skilled in the art. Drawings are merely for illustrating the aim of the preferable embodiment, and not for limiting the present disclosure. Elements having the same reference numeral designations represent same elements throughout the whole drawings. In the drawings:

FIG. 1 shows a front stereo diagram of a heat sink provided in some embodiments of the present disclosure;

FIG. 2 shows a left view of the heat sink provided in some embodiments of the present disclosure;

FIG. 3 shows a top view of the heat sink provided in some embodiments of the present disclosure;

FIG. 4 shows a back view of the heat sink provided in some embodiments of the present disclosure;

FIG. 5 shows a stereo diagram of the bottom of the heat sink provided in some embodiments of the present disclosure;

FIG. 6 shows an upward view of the heat sink provided in some embodiments of the present disclosure.

### PREFERABLE EMBODIMENT OF THE DISCLOSURE

The example embodiments of the present publication are to be further elaborated in detail as follows with reference to the accompanying drawings. The drawings show the example embodiments of the present publication, whereas it should be appreciated that implementations of the present publication in various manners should not be limited by the embodiments elaborated herein. Reversely, the embodiments are provided for better understanding of the present publication, and completely conveying the whole scope of the present publication to those skilled in the art.

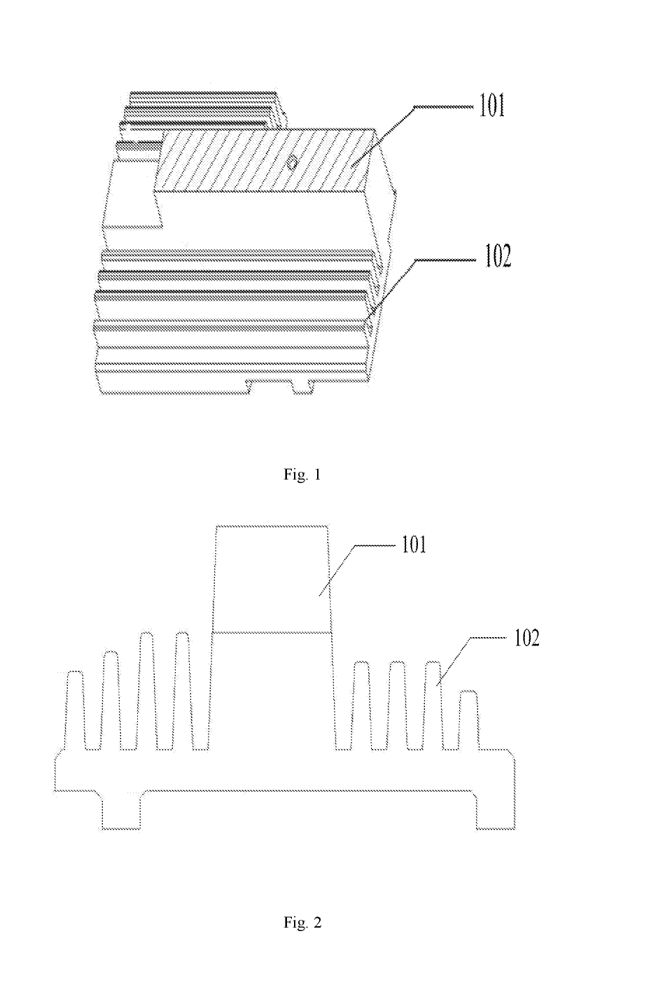

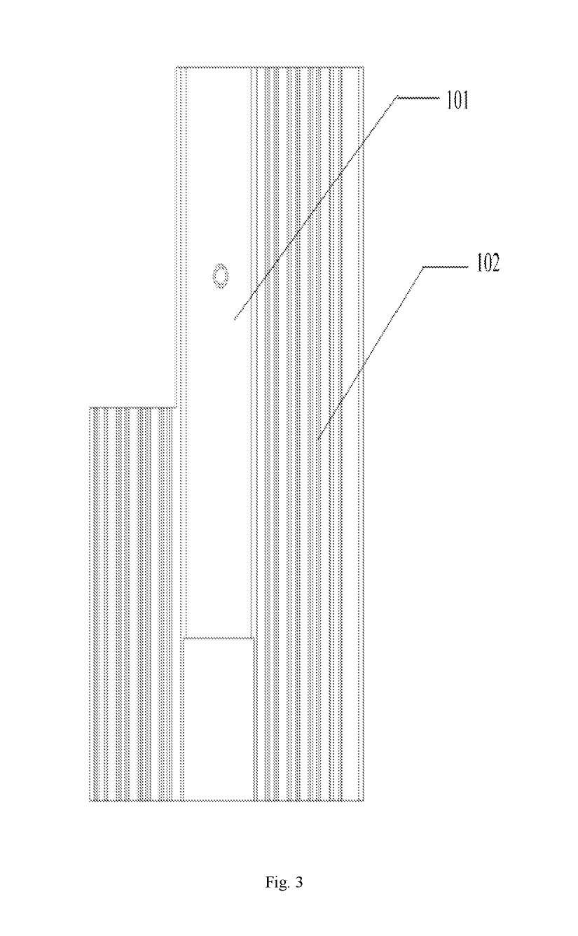

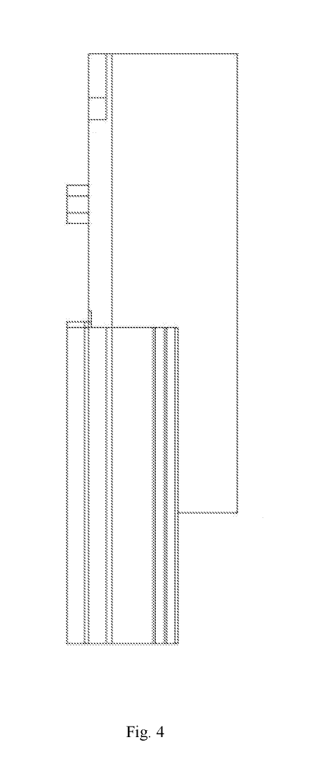

FIG. 1 shows a front stereo diagram of a heat radiator provided in an embodiment of the present invention. As shown in FIG. 1, an embodiment of the present disclosure provides a heat sink, an upper portion of which is formed by a solid aluminium block boss 101, and a lower portion of which is formed by an aluminium substrate, wherein at least one fin 102 is configured on either side of the solid aluminium block boss 101. The upper portion of the heat sink is a solid aluminium block boss 101, which is further provided with a thermal interface material thereon. Spray painting process is further performed on the thermal interface material. The merit is to smooth the thermal interface material to facilitate its subsequent close attachment to the aluminium sheet in the metal shell. At least one fin 102 is configured on either side of the solid aluminium block boss 101, and spray coating is performed on the surfaces of the heat radiating fins 102 The numbers and/or lengths of the heat radiating fins 102 on both sides of the solid aluminium block boss 101 may be same or different. FIG. 2 shows a left view of the heat sink provided in an embodiment of the present disclosure. It can be clearly seen from FIG. 2 that the numbers of heat radiating fins 102 on both sides of the solid aluminium block boss 101 may be different. FIG. 3 shows a top view of the heat sink provided in an embodiment of the present disclosure. It can be clearly seen from FIG. 3 that the lengths of the heat radiating fins 102 on both sides of the solid aluminium block boss 101 may be obviously different. FIG. 4 shows a back view of the heat sink provided in an embodiment of the present disclosure. It can be clearly seen from FIG. 4 that the lengths of the heat radiating fins on one side of the solid aluminium block boss is remarkably shorter than the length of the boss.

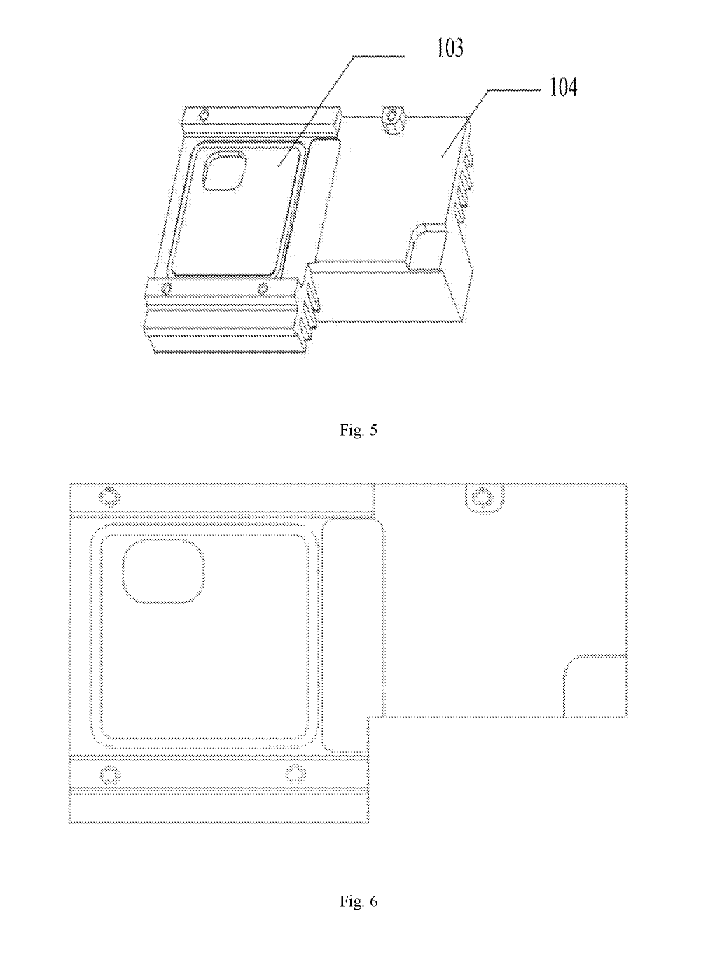

FIG. 5 shows a stereo diagram of the bottom of the heat sink provided in an embodiment of the present disclosure. As shown in FIG. 5, the bottom of the heat sink is formed by an aluminium substrate, and the aluminium substrate is further configured with a rectangular-ambulatory-plane groove 103. The rectangular-ambulatory-plane groove 103 is attached with an EMI gasket. Spray painting process is performed on other aluminium substrates on the bottom 104, such that the aluminium substrates may be better attached to the heat source element to facilitate the heat conduction from the heat source element. FIG. 6 shows an upward view of the heat sink.

When the heat sink is in operation, the heat sink is mounted between the heat source element and the metal shell of the electronic device, wherein the bottom of the heat sink is closely attached to the heat source element, such as CPU, and the top of the heat sink is closely attached to the back of the metal shell of the electronic device. In order to attach the heat sink and the heat source element closely to the metal shell of the electronic device, the three can be fixed via a fixing element, such as a bolt or a snap ring. For example, holes can be drilled in corresponding positions in the metal shell of the electronic device, the heat sink, and the circuit board where the heat source element locates, such that a bolt may be inserted from the location hole in the metal shell of the electronic device through the location hole in the heat sink into corresponding location hole in the circuit board where the heat source element locates, and then rotated into a nut on the circuit board end for fixing.

In this way, the heat generated from the heat sink may be instantly conducted to the heat sink via the aluminium substrates on the bottom of the heat sink. The heat sink expands the heat radiating area by the manner of fins, conducting the heat to the inside of the machine by natural convection and radiation. A portion of the heat within the machine is dissipated via wind holes by natural convection, and the rest of the heat is conducted to the aluminium sheet in the shell via the solid aluminium block boss and the thermal interface material on the top of the heat sink, and directly dissipated to the outside of the machine by natural convection and radiation.

The above is merely a preferable embodiment of the present disclosure, and is not intended for limiting the disclosure. Any amendments or equivalent replacements made within the spirit and principle of the present disclosure should be covered by the protection scope of the present disclosure.

1-10. (canceled)

11. A heat sink, wherein an upper portion of the heat sink is formed by a solid aluminium block boss, a lower portion of the heat sink is formed by an aluminium substrate, and at least one fin is configured on either side of the solid aluminium block boss.

12. The heat sink according to claim 11, wherein the solid aluminium block boss is further provided with a thermal interface material.

13. The heat sink according to claim 12, wherein spray painting process is further performed on the thermal interface material, and/or spray coating is performed on the surfaces of heat radiating fins.

14. The heat sink according to claim 11, wherein the numbers and/or lengths of the heat radiating fins on both sides of the solid aluminium block boss may be same or different.

15. The heat sink according to claim 11, wherein spray painting process is performed on the aluminium substrate.

16. The heat sink according to claim 11, wherein a rectangular-ambulatory-plane groove is arranged on the aluminium substrate.

17. The heat sink according to claim 16, wherein the rectangular-ambulatory-plane groove is attached with an EMI gasket.

18. The heat sink according to claim 11, wherein the heat sink is mounted between a heat source element and a metal shell of the electronic device, wherein the aluminium substrate on the bottom of the heat sink is closely attached to the heat source element, and the top of the heat sink is closely attached to the back of the metal shell of the electronic device.

19. The heat sink according to claim 18, wherein the heat sink and heat source element are closely fixed to the metal shell of the electronic device via a fixing element.

20. The heat sink according to claim 19, wherein the fixing element is a bolt or a snap ring.
